(19) United States
(12) Patent Application Publication
(10) Pub. No.: US 2015/0364721 A1
(43) Pub. Date: Dec. 17, 2015

(54) DISPLAY DEVICE

(71) Applicant: Japan Display Inc., Tokyo (JP)

(72) Inventors: Takeshi KURIYAGAWA, Tokyo (JP); Takuo Kaito, Tokyo (JP)

(21) Appl. No.: 14/735,899

(22) Filed: Jun. 10, 2015

(30) Foreign Application Priority Data
Jun. 11, 2014 (JP) 2014-120438

(51) Int. Cl. H01L 51/52; H01L 51/00; H01L 27/32

(52) U.S. Cl. CPC H01L 51/5259; H01L 51/5246; H01L 27/322; H01L 51/0097; H01L 2251/5338

(57) ABSTRACT

A display device includes a first substrate, a light emitting element located on the first substrate, a second substrate having dampproofness and facing the first substrate, a first barrier layer located on the first substrate and having a higher level of dampproofness than the dampproofness of the second substrate, an organic layer located on the first barrier layer at a position facing the light emitting element, and a second barrier layer located on the organic layer and having a higher level of dampproofness than the dampproofness of the second substrate.

### CROSS-REFERENCE TO RELATED APPLICATIONS

This application is based upon and claims the benefit of priority from the prior Japanese Patent Application No. 2014-120438, filed on Jun. 11, 2014, the entire contents of which are incorporated herein by reference.

### FIELD

The present invention relates to a display device, and specifically to a film structure on the side of a counter substrate facing a substrate on which a light emitting element is provided.

### BACKGROUND

Recently, light-emitting display devices for uses in mobile devices are increasingly strongly desired to have higher definition and consume less power. Examples of display devices for uses in mobile devices are liquid crystal display devices (LCDs), display devices using elements for spontaneously emitting light, for example, organic light-emitting diode (OLED) display devices, electronic paper display devices, and the like.

Organic light-emitting diode display devices and electronic paper display devices, among the above, do not require a backlight unit or a polarization plate, which is required in liquid crystal display devices, and also use a light emitting element driven at a low voltage. For these reasons, these display devices are a target of attention as thin light emitting display devices consuming low power. These display devices can be merely formed of thin films, and thus can be made flexible as described in, for example, Japanese Laid-Open Patent Publication No. 2007-183605. In addition, these display devices do not use a glass substrate, and therefore are lightweight and are not easily breakable. For these reasons, organic light-emitting diode display devices and electronic paper display devices attract a lot of attention. However, it is known as one of the problems of the OLED that the light emitting material used for a light emitting element, for example, an organic light-emitting element located in each of pixels of the OLED, is deteriorated when being exposed to oxygen or moisture and the emission efficiency of the OLED is decreased. Particularly, in a flexible display, because a very thin flexible substrate including a resin material is used, the oxygen and moisture from the exterior reaches to the light emitting material through the flexible substrate. As a result, the light emitting element is deteriorated.

### SUMMARY

A display device in an embodiment according to the present invention includes a first substrate, a light emitting element located on the first substrate, a second substrate having dampproofness and facing the first substrate, a first barrier layer located on the second substrate and having a higher level of dampproofness than the dampproofness of the second substrate, an organic layer located on the first barrier layer at a position facing the light emitting element, and a second barrier layer located on the organic layer and having a higher level of dampproofness than the dampproofness of the second substrate.

### BRIEF DESCRIPTION OF DRAWINGS

FIG. 1 is a cross-sectional view showing a layer structure of a display device in an embodiment according to the present invention;

FIG. 2 is an isometric view of a display device in an embodiment according to the present invention;

FIG. 3 is a plan view of the display device in the embodiment according to the present invention;

FIG. 4A is a cross-sectional view of the display device in the embodiment according to the present invention, taken along line A-B in FIG. 3;

FIG. 4B is a cross-sectional view of a display device in an embodiment according to the present invention, taken along line A-B in FIG. 3;

FIG. 5 is a view showing a step, in a method for producing the display device in the embodiment according to the present invention, of forming a first substrate, light emitting elements, and a protective layer on a first support substrate;

FIG. 6 is a view showing a step, in the method for producing the display device in the embodiment according to the present invention, of forming a second substrate and a first barrier layer on a second support substrate;

FIG. 7 is a view showing a step, in the method for producing the display device in the embodiment according to the present invention, of forming color filters and a light blocking layer;

FIG. 8 is a view showing a step, in the method for producing the display device in the embodiment according to the present invention, of forming a second barrier layer;

FIG. 9 is a view showing a step, in the method for producing the display device in the embodiment according to the present invention, of bonding the first support substrate and the components provided thereon, and the second support substrate and the components provided thereon;

FIG. 10 is a view showing a step, in the method for producing the display device in the embodiment according to the present invention, of peeling off the first support substrate and the second support substrate;

FIG. 11 is a cross-sectional view showing a layer structure of a first barrier layer in a display device in an embodiment according to the present invention; and

FIG. 12 is a cross-sectional view showing a layer structure of a second barrier layer in the display device in the embodiment according to the present invention.

### DESCRIPTION OF EMBODIMENTS

Hereinafter, embodiments of the present invention will be described with reference to the drawings. The disclosure is merely exemplary, and alternations and modifications conceivable by a person of ordinary skill in the art without departing from the gist of the present invention are duly encompassed in the scope of the present invention. In the drawings, components may be shown schematically regarding the width, thickness, shape and the like, instead of being shown in accordance with the actual sizes. The drawings are merely exemplary and do not limit the interpretations of the present invention in any way. In the specification and the drawings, components that are substantially the same as those described before bear the identical reference signs thereto, and detailed descriptions thereof may be omitted.

### EMBODIMENT 1

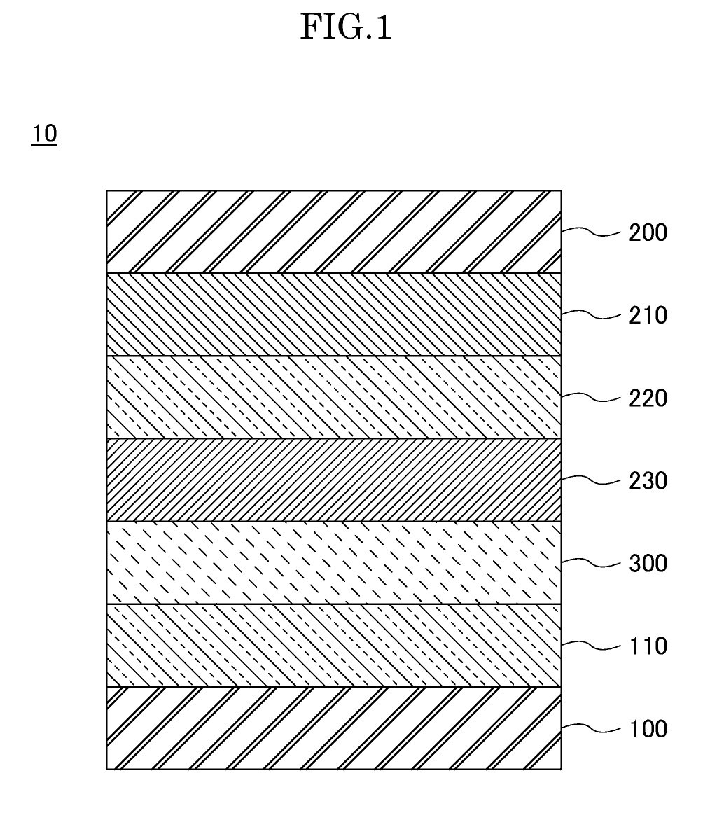

With reference to FIG. 1, a layer structure of a display device in embodiment 1 according to the present invention will be described. In embodiment 1, a layer structure of a top emission-type flexible display device including a light emitting element will be described.

### <Layer Structure of the Display Device>

FIG. 1 is a cross-sectional view of a layer structure of a display device 10 in embodiment 1 according to the present invention. As shown in FIG. 1, the display device 10 includes a first substrate 100 and a light emitting element 110 located on the first substrate 100. The display device 10 also includes a second substrate 200 having dampproofness, a first barrier layer 210 located on the second substrate 200 and having a higher level of dampproofness than the dampproofness of the second substrate 200, an organic layer 220 located on the first barrier layer 210 at a position corresponding to the light emitting element 110, and a second barrier layer 230 located on the organic layer 220 and having a higher level of dampproofness than that of the second substrate 200. The first substrate 100 and the components provided thereon, and the second substrate 200 and the components provided thereon, are bonded together with a filler 300 such that a top surface of the first substrate 100 and a top surface of the second substrate 200 face each other. The top surface of the first substrate 100 is a surface thereof on the side of the second substrate 200, and the top surface of the second substrate 200 is a surface thereof on the side of the first substrate, in the state where the components are bonded together. A component having “dampproofness” is low in moisture permeability and is not permeated by vapor easily. In other words, a component having dampproofness has a blocking ability against moisture.

The first substrate 100 and the second substrate 200 may be formed of a flexible material. Specifically, the first substrate 100 and the second substrate 200 may be formed of a polyimide resin, an acrylic resin or the like. In this case, the first substrate 100 has a thickness of, preferably, 3 μm or greater and 50 μm or less, and more preferably, 5 μm or greater and 20 μm or less. In a top emission-type display device as in embodiment 1, light released from the light emitting element 110 is output from the side of the second substrate 200. Therefore, the first substrate 100 does not absolutely need to have a high light transmittance. For example, the first substrate 100 may have impurities incorporated thereto in order to have an improved resistance against a heat treatment performed in a step of forming a transistor. Even if the light transmittance of the first substrate 100 is lowered due to the impurities, there is no problem. By contrast, the second substrate 200 is preferably formed of a material having a high light transmittance. In the case of a bottom emission-type display device, light released from a light emitting element is output from the side of a first substrate, and therefore it is preferable that the first substrate is formed of a material having a high light transmittance.

The light emitting element 110 includes a transistor layer and a light emitting layer. The transistor layer includes a transistor element and a line. The transistor element may be an amorphous silicon transistor element, a polysilicon transistor element, a single crystalline silicon transistor element, an oxide semiconductor transistor element, an organic semiconductor transistor element, or the like. The light emitting element 110 does not absolutely need to include a transistor element. For example, the line and the light emitting layer may be provided on the first substrate 100 as in a passive light emitting device. The light emitting layer may be formed of an organic EL layer or an inorganic EL layer. The above-described light emitting layer that is of a spontaneous light emitting type may be replaced with a reflective display layer such as in an electronic paper display device.

The light emitting element 110 may include an underlying barrier layer located between the first substrate 100 and the transistor layer. The underlying barrier layer suppresses impurities from the first substrate 100 or moisture entering from the side of the first substrate 100, from diffusing into the transistor layer or the light emitting layer. The underlying barrier layer may be formed of a silicon nitride film (SiNₓ film), a silicon oxide film (SiOₓ film), a silicon nitride oxide film (SiNₓO_{y} film), a silicon oxide nitride film (SiOₓN_{y} film), an aluminum nitride film (AlNₓ film), an aluminum oxide film (AlOₓ film), an aluminum nitride oxide film (AlNₓO_{y} film), an aluminum oxide nitride film (AlOₓN_{y} film) or the like (x and y each represent an arbitrary numeral figure). The underlying barrier layer may be formed of a stack of such films. The “silicon nitride oxide film” is a silicon nitride film containing oxygen in an amount smaller than that of nitrogen. The “silicon oxide nitride film” is a silicon oxide film containing nitrogen in an amount smaller than that of oxygen.

The first barrier layer 210 may have a single film structure or a stacked film structure. The first barrier layer 210 includes a first damp-proof film containing silicon and nitrogen and having a higher level of dampproofness than the dampproofness of the second substrate 200. In the case where the first barrier layer 210 has a single film structure, the first damp-proof film is the first barrier layer 210. In the case where the first barrier layer 210 has a stacked film structure, at least one of the films included in the first barrier layer 210 is the first damp-proof film. The first damp-proof film may be an SiNₓ film, an SiNₓO_{y} film, or a such a film containing impurities. Alternatively, the first damp-proof film may be an AlNₓ film, an AlNₓO_{y} film, any other metal nitride film, or any other metal nitride oxide film.

The second barrier layer 230 may have a single film structure or a stacked film structure. The second barrier layer 230 includes a second damp-proof film containing silicon and nitrogen and having a higher level of dampproofness than the dampproofness of the second substrate 200. In the case where the second barrier layer 230 has a single film structure, the second damp-proof film is the second barrier layer 230. In the case where the second barrier layer 230 has a stacked film structure, at least one of the films included in the second barrier layer 230 is the second damp-proof film. The second damp-proof film may be an SiNₓ film, an SiNₓO_{y} film, or a such a film containing impurities. Alternatively, the second damp-proof film may be an AlNₓ film, an AlNₓO_{y} film, any other metal nitride film, or any other metal nitride oxide film. The second damp-proof film may have a higher level of dampproofness than the dampproofness of the organic layer 220 to have a block function against moisture and gas released from the organic layer 220.

The first damp-proof film and the second damp-proof film each preferably have a thickness of 50 nm or greater in order to have a sufficient barrier property against moisture. The first damp-proof film and the second damp-proof film represented by an SiNₓ film have a very high stress, and therefore, each preferably have a thickness of 500 nm or less. The first damp-proof film of the first barrier layer 210 and the second damp-proof film of the second barrier layer 230 may be formed of the same material or different materials.

The organic layer 220 may be a color filter that transmits light of a specific wavelength band. The color filter is located in correspondence with each of pixels provided in a display area of the display device 10. The organic layer 220 may be a light blocking film located between the pixels and having a light blocking property. The organic layer 220 may act as both of a color filter and a light blocking film.

As described above, the display device 10 in embodiment 1 according to the present invention includes a barrier layer between the second substrate 200 and the organic layer 220 and between the organic layer 220 and the light emitting element 110. Therefore, entrance of moisture from the side of the second substrate 200 is suppressed. As a result, deterioration of the light emitting element 110 is prevented. In addition, moisture or a gas component desorbed from the organic layer 220 is suppressed from reaching the light emitting element 110, and therefore, deterioration of the light emitting element 110 is suppressed.

### EMBODIMENT 2

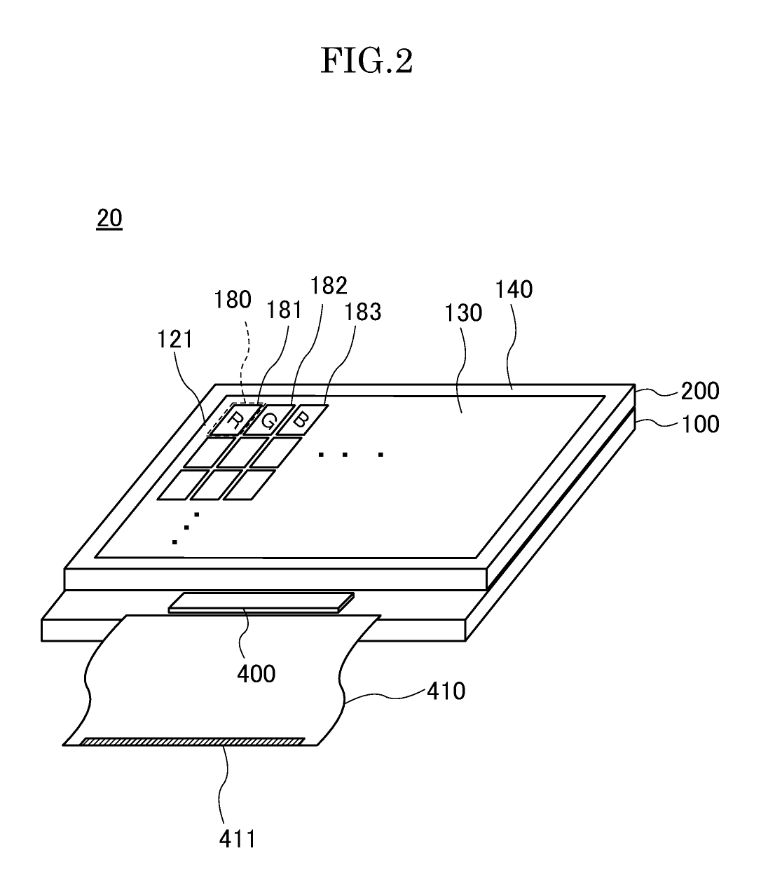

With reference to FIG. 2 through FIG. 4, a structure of a display device in embodiment 2 according to the present invention will be described. In embodiment 2, a display device including a layer structure as described above in embodiment 1 and external elements, for example, a driver IC 400 and an FPC (flexible printed circuit) 410 will be described. In embodiment 2, a display device having a “white+CF structure” that is advantageous for realizing a higher definition will be described as an example of the flexible display device.

### <Structure of the Display Device>

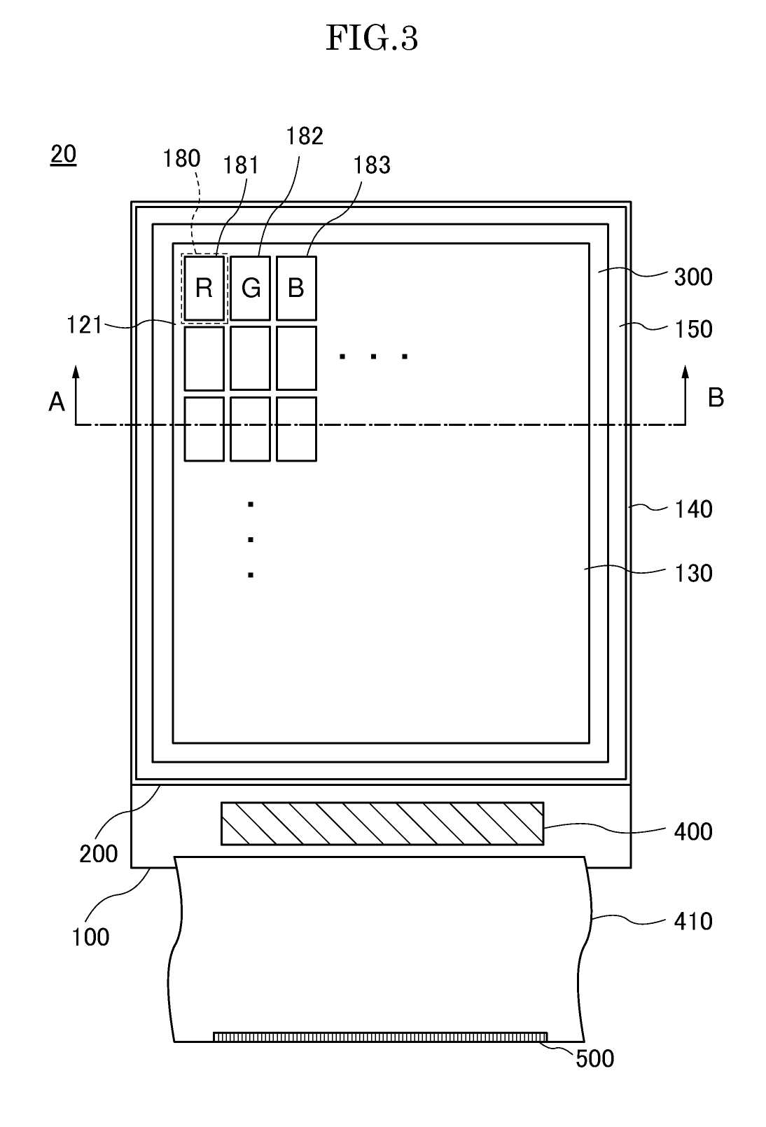

FIG. 2 is an isometric view of a display device 20 in embodiment 2 according to the present invention. FIG. 3 is a plan view of the display device 20 in embodiment 2 according to the present invention. As shown in FIG. 2 and FIG. 3, the display device 20 in embodiment 2 includes a first substrate 100, a second substrate 200 facing the first substrate 100, the driver IC 400 provided in an area of the first substrate 100 that is exposed from the second substrate 200, and the FPC (flexible printed circuit) 410. The FPC 410 includes a terminal part 411 connected to a controller circuit that controls a driving circuit.

The first substrate 100 includes pixels 180, each including a light emitting element, in a display area 130. In the display device 20 in embodiment 2, each pixel 180 includes a light emitting element. The light emitting element releases white light from a top surface thereof. On the second substrate 200, a light blocking layer 121 and color filters 181 through 183 are provided. The light blocking layer 121 includes openings in correspondence with the pixels 180. The color filters 181 through 183 are provided in correspondence with the openings, and each transmit light of a specific wavelength band. The first substrate 100 and the components provided thereon, and the second substrate 200 and the components provided thereon, are bonded together with a sealing member 150 and a filler 300. The sealing member 150 is located in a peripheral area 140, which is around the display area 130 in which the pixels 180 are located. The filler 300 is provided to fill an area enclosed by the sealing member 150.

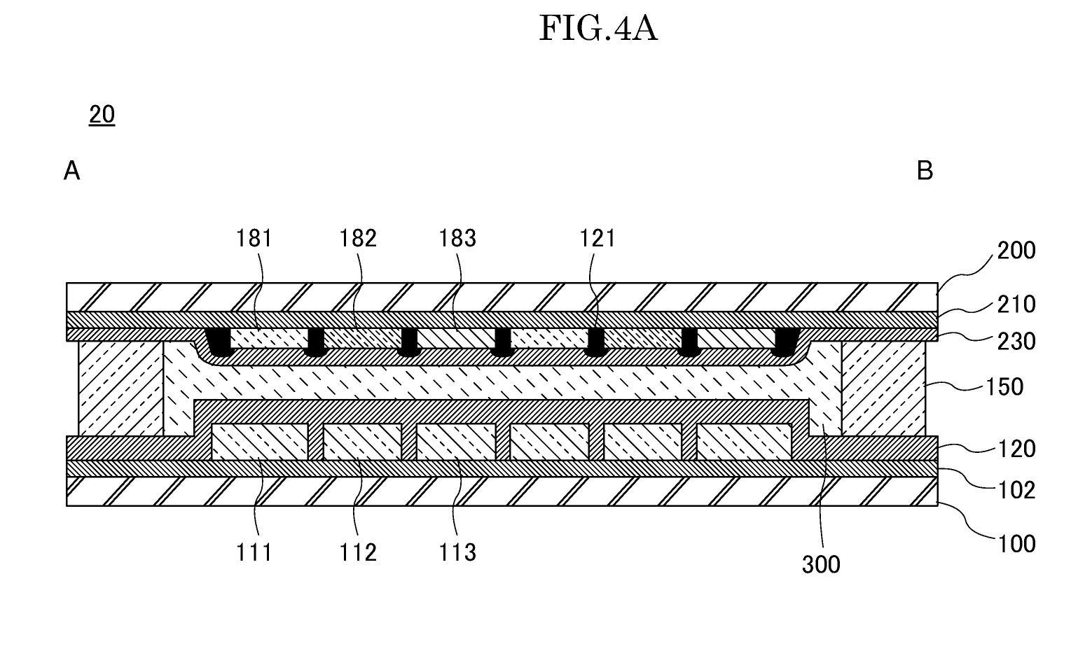

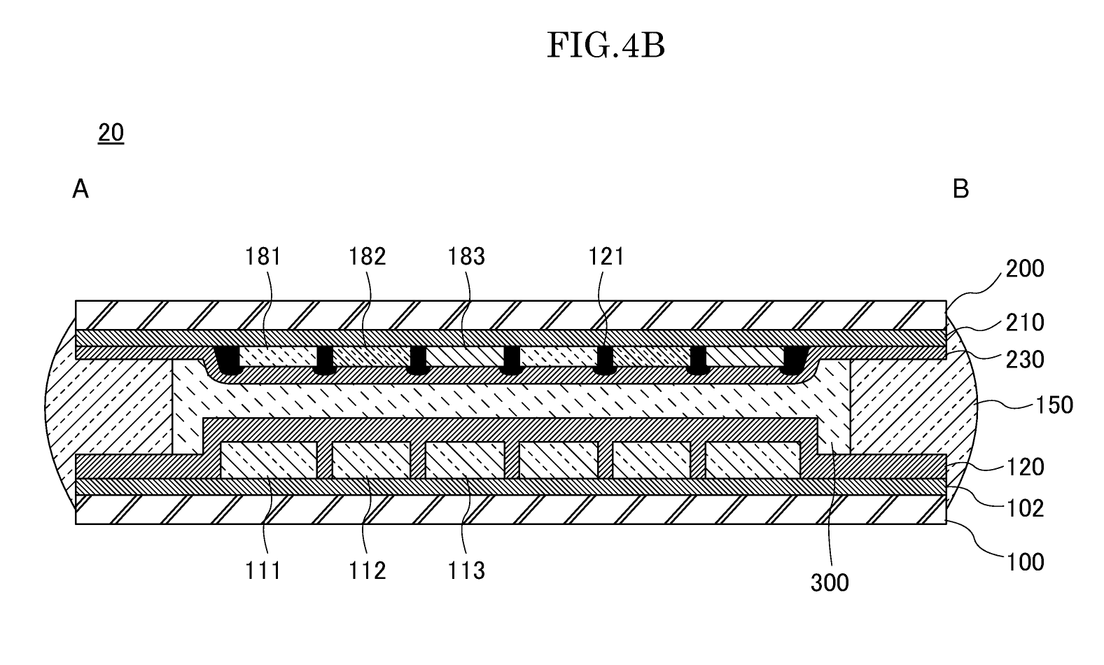

FIG. 4A is a cross-sectional view of the display device 20 in embodiment 2 according to the present invention, taken along line A-B in FIG. 3. As shown in FIG. 4A, the display device 20 in embodiment 2 includes the first substrate 100, which is flexible, an underlying barrier layer 102, light emitting elements 111, 112 and 113, and a protective layer 120. The underlying barrier layer 102 is located on the first substrate 100. The underlying barrier layer 102 has a higher level of dampproofness than that of the first substrate 100 and suppresses diffusion of impurities from the first substrate 100. The light emitting elements 111, 112 and 113 are located in the display area 130 on the first substrate 100. The protective layer 120 is located in the display area 130 and the peripheral areal 140 so as to cover the light emitting elements 111 through 113, and is in contact with the underlying barrier layer 102 in the peripheral areal 140 to seal the light emitting elements 111, 112 and 113.

The display device 20 also includes the second substrate 200, which is flexible, a first barrier layer 210, the color filters 181, 182 and 183, the light blocking layer 121, and a second barrier layer 230. The first barrier layer 210 is located on the first substrate 200. The first barrier layer 210 has a higher level of dampproofness than that of the second substrate 200. The color filters 181, 182 and 183 are provided in correspondence with the light emitting elements 111, 112 and 113 located in the display area 130. The light blocking layer 121 is located between the color filters 181 through 183. The second barrier layer 230 is located in the display area 130 and the peripheral areal 140 so as to cover the light blocking layer 121 and the color filters 181, 182 and 183, and is in contact with the first barrier layer 210 in the peripheral areal 140 to seal the light blocking layer 121 and the color filters 181 through 183. In this example, the color filters correspond to the three RGB colors. Alternatively, the color filters may correspond to the four RGBW colors including the RGB colors and white, or correspond to four colors including the RGB colors and any other color.

The first substrate 100 and the components provided thereon, and the second substrate 200 and the components provided thereon, are bonded together with the sealing member 150 and the filler 300. The sealing member 150 is in contact with the second barrier layer 230 and the protective layer 120 in the peripheral area 140. The present invention is not limited to having the structure shown in FIG. 4A. One or a plurality of layers among the underlying barrier layer 102, the protective layer 120, the first barrier layer 210 and the second barrier layer 230 may be omitted in the area where the sealing member 150 is located.

In FIG. 3 and FIG. 4A, the sealing member 150 is provided slightly inner to edges of the first substrate 100 and the second substrate 200. Alternatively, as shown in FIG. 4B, the sealing member 150 may be provided so as to cover the edges of the first substrate 100 and the second substrate 200 in order to improve the dampproofness against moisture entering from the edges. In this case, another sealing member may be provided outer to the sealing member 150. The sealing member 150 shaped as shown in FIG. 4B may be formed as follows. In the state where the sealing member 150 in an uncured state is provided between the second barrier layer 230 and the protective layer 120, the sealing member 150 is pressed by the first substrate 100 and the second substrate 200 to be expanded.

As described above, the display device 20 in embodiment 2 according to the present invention includes a barrier layer between the second substrate 200 and the color filters 181 through 183 and between the color filters 181 through 183 and the light emitting elements 111 through 113. Therefore, entrance of moisture from the side of the second substrate 200 is suppressed. In addition, moisture or a gas component desorbed from the color filters 181 through 183 is suppressed from reaching the light emitting elements 111 through 113, and entrance of moisture from a peripheral area of the display device 20 is suppressed. Therefore, deterioration of the light emitting elements 111 through 113 is prevented.

### <Method for Producing the Display Device>

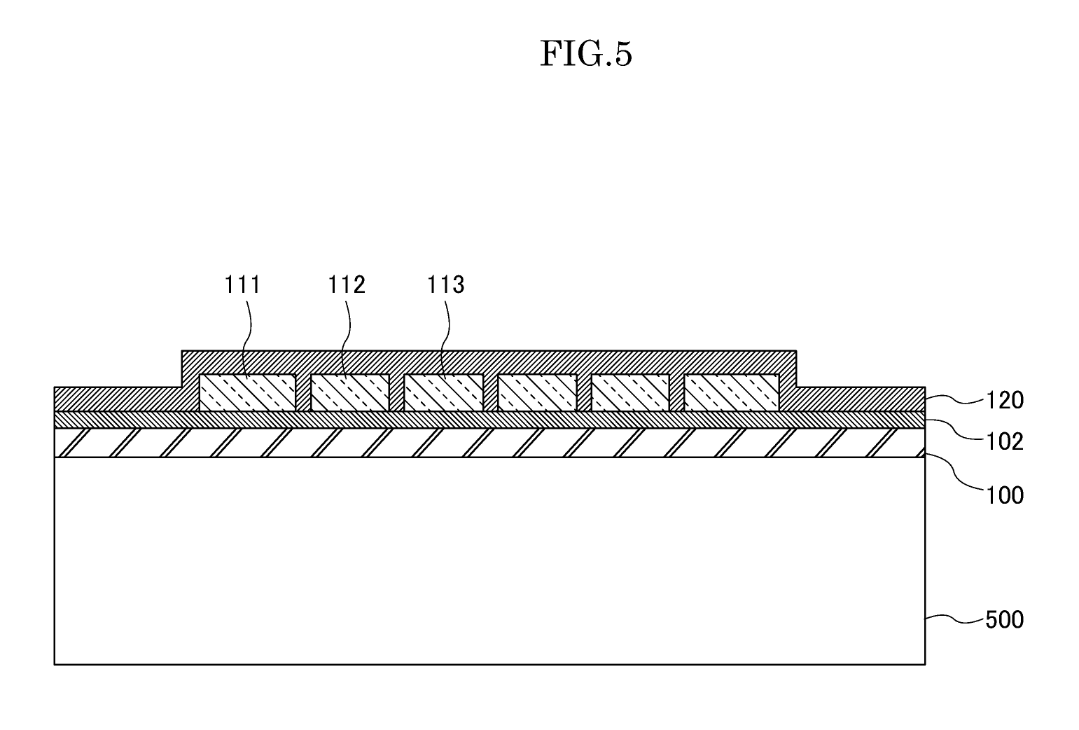

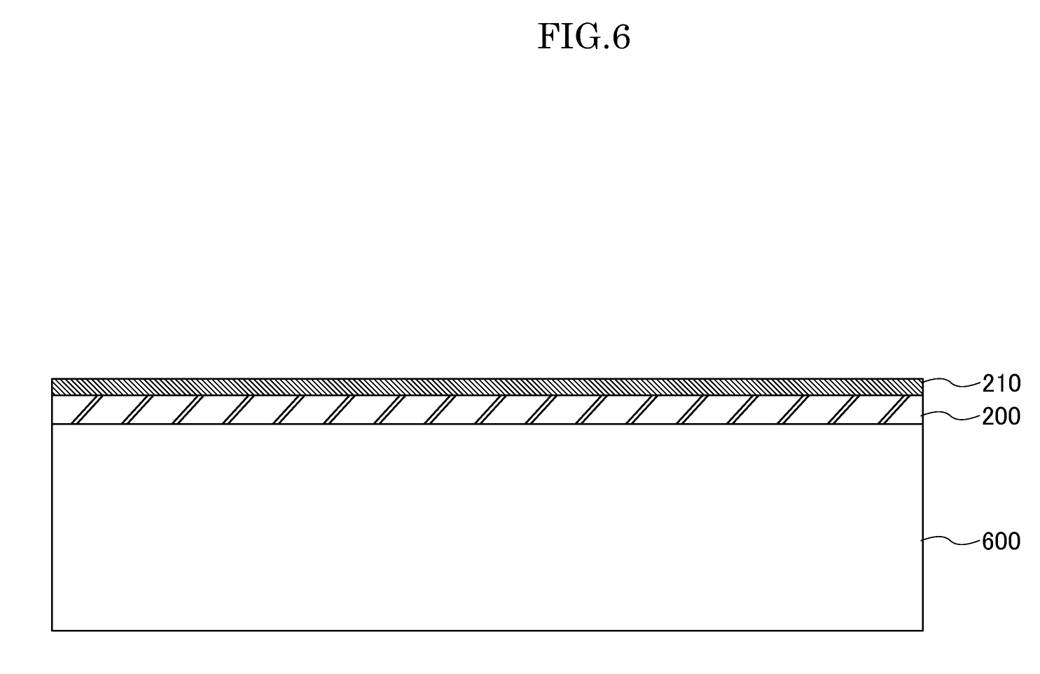

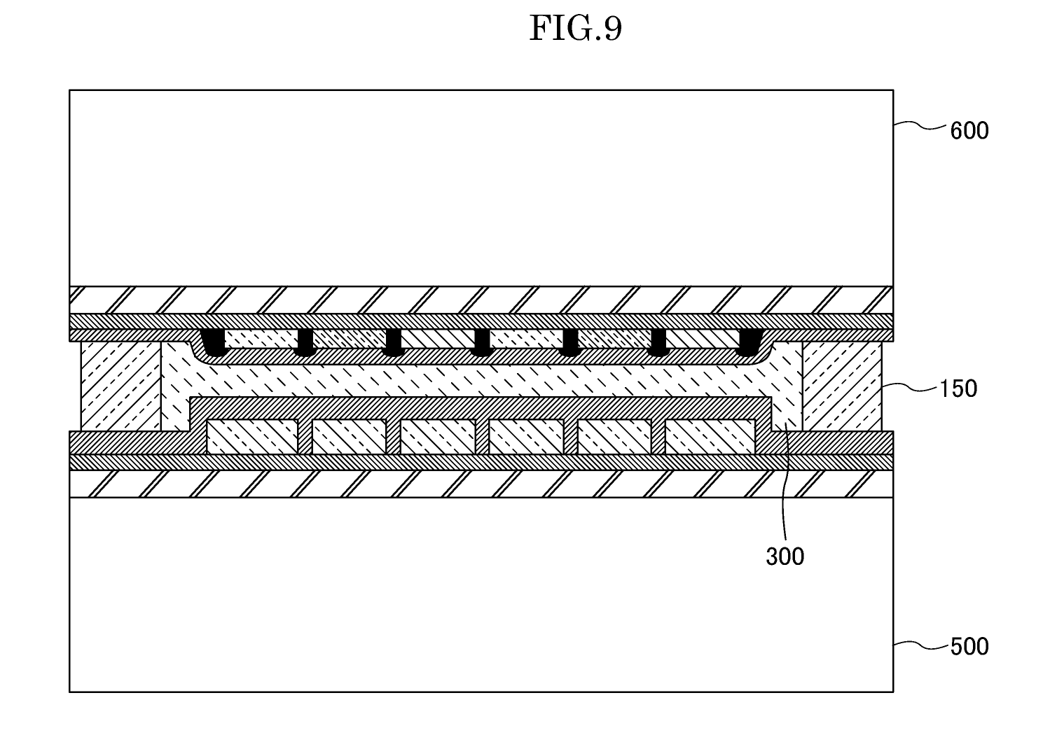

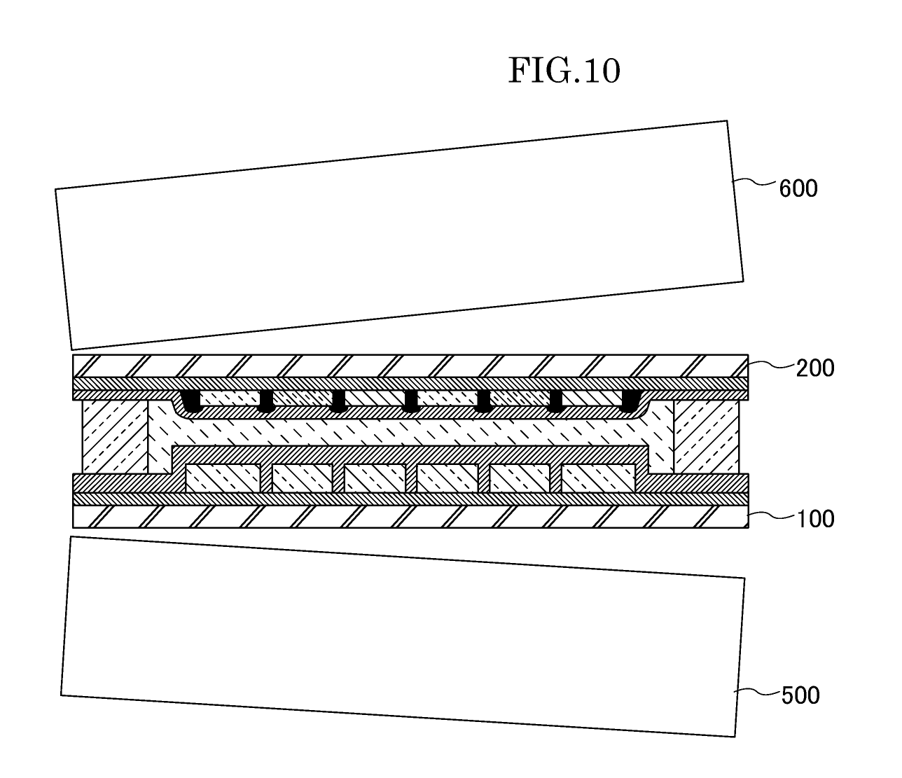

With reference to FIG. 5 through FIG. 10, a method for producing the display device 20 in embodiment 2 according to the present invention will be described. More specifically, with reference to FIG. 5, a process of producing the first substrate 100 and the components provided thereon will be described. With reference to FIG. 6 through FIG. 8, a process of producing the second substrate 200 and the components provided thereon will be described. With reference to FIG. 9 and FIG. 10, a process of bonding the first substrate 100 and the components provided thereon, and the second substrate 200 and the components provided thereon, and peeling off a first support substrate 500 and a second support substrate 600 (step of forming a flexible display device) will be described. In the method described below, the flexible substrates are respectively formed on two rigid support substrates, light emitting elements are formed on one of the two flexible substrates, color filters are formed on the other flexible substrate, the resultant substrates are bonded together, and the support substrates are peeled off.

FIG. 5 shows a step in the method for producing the display device 20 in embodiment 2 according to the present invention. In the step shown in FIG. 5, the first substrate 100, the light emitting elements 111, 112 and 113, and the protective layer 120 are formed on the first support substrate 500. Referring to FIG. 5, first, a substrate that is more rigid than at least the first substrate 100 is prepared as the first support substrate 500. The first support substrate 500 may be, for example, a glass substrate. On the first support substrate 500, the flexible first substrate 100 is formed. The first substrate 100 may be formed of a material described in embodiment 1.

Next, the underlying barrier layer 102 is formed on the first substrate 100. The underlying barrier layer 102 is provided to suppress diffusion, to the transistor layer and the light emitting layer, of impurities from the first substrate 100 and moisture entering from the side of the first substrate 100. The underlying barrier layer 102 may be formed of a material described in embodiment 1. Next, the light emitting elements 111, 112 and 113 each including the transistor layer and the light emitting layer are formed. In a heat treatment performed in a step of forming the underlying barrier layer 102 and the transistor layer, the temperature is desirably lower than the glass transition point of the first substrate 100. Next, the protective layer 120 is formed on the light emitting elements 111, 112 and 113. The protective layer 120 is desirably formed at a temperature lower than the glass transition point of the organic layer included in the light emitting layer in each of the light emitting elements 111, 112 and 113.

FIG. 6 shows a step in the method for producing the display device 20 in embodiment 2 according to the present invention. In the step shown in FIG. 6, the second substrate 200 and the first barrier layer 210 are formed on the second support substrate 600. Referring to FIG. 6, first, a substrate that is more rigid than at least the second substrate 200 is prepared as the second support substrate 600. The second support substrate 600 may be, for example, a glass substrate. On the second support substrate 600, the flexible second substrate 200 is formed. The second substrate 200 may be formed of a material described in embodiment 1. Next, the first barrier layer 210 is formed on the second substrate 200. The first barrier layer 210 may be formed of a material described in embodiment 1. The first barrier layer 210 is desirably formed at a temperature lower than the glass transition point of the second substrate 200.

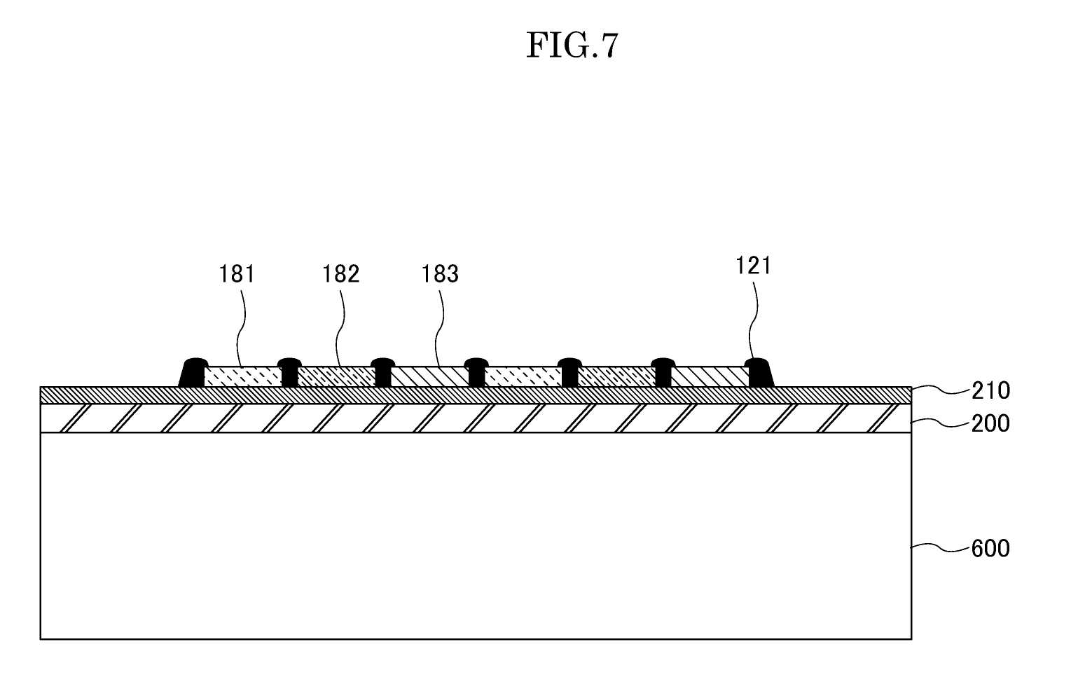

FIG. 7 shows a step in the method for producing the display device 20 in embodiment 2 according to the present invention. In the step shown in FIG. 7, the color filters 181 through 183 and the light blocking layer 121 are formed. As shown in FIG. 7, the color filter 181 transmitting light of a red wavelength band, the color filter 182 transmitting light of a green wavelength band and the color filter 183 transmitting light of a blue wavelength band are formed at such positions that correspond to the respective light emitting elements 111 through 113 in the completed display device 20, and the light blocking layer 121 is formed between the color filters 181 through 183. In the example shown in FIG. 7, after the color filters 181 through 183 are formed, the light blocking layer 121 is formed. Alternatively, the color filters 181 through 183 may be formed after the light blocking layer 121 is formed.

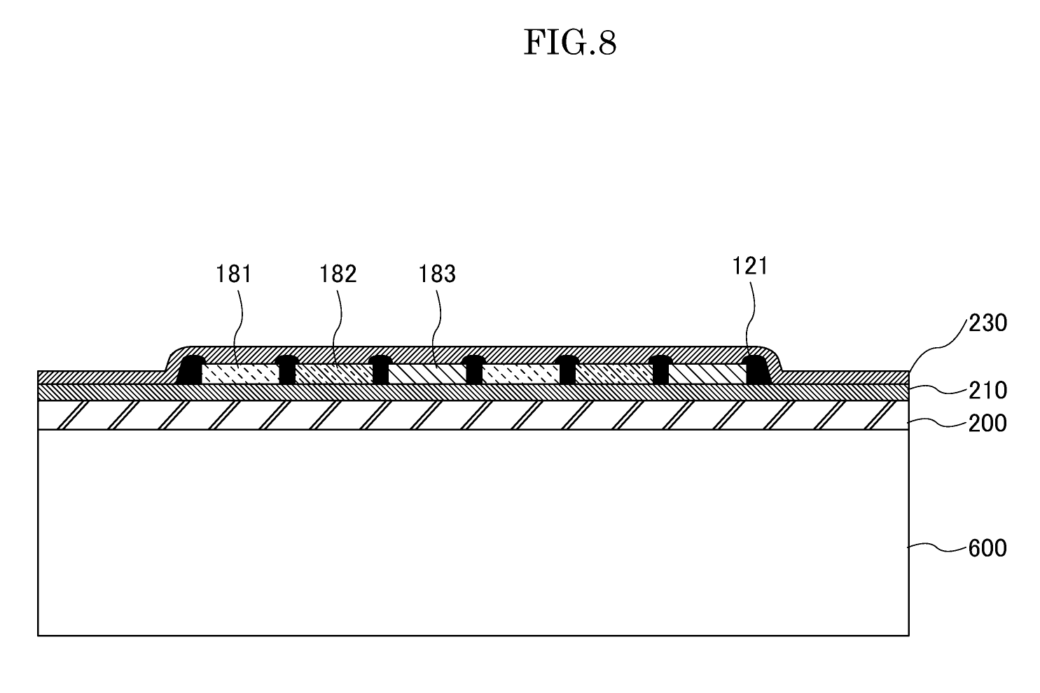

FIG. 8 shows a step in the method for producing the display device 20 in embodiment 2 according to the present invention. In the step shown in FIG. 8, the second barrier layer 230 is formed. As shown in FIG. 8, the second barrier layer 230 is formed so as to cover the color filters 181, 182 and 183 and the light blocking layer 121. The second barrier layer 230 may be formed of a material described in embodiment 1. The second barrier layer 230 is desirably formed at a temperature lower than the glass transition point of the second substrate 200, the color filters 181, 182 and 183 and the light blocking layer 121. Between the color filters 181-183/light blocking layer 121 and the second barrier layer 230, an overcoat layer may be formed in order to reduce the stepped portion made by the color filters 181, 182 and 183 and the light blocking layer 121.

Next, the first support substrate 500 and the components provided thereon shown in FIG. 5, and the second support substrate 600 and the components provided thereon shown in FIG. 8, are bonded together via the sealing member 150 and the filler 300. FIG. 9 shows a step in the method for producing the display device 20 in embodiment 2 according to the present invention. In the step shown in FIG. 9, the first support substrate 500 and the components provided thereon, and the second support substrate 600 and the components provided thereon, are bonded together. The sealing member 150 and the filler 300 are formed on the first support substrate 500 and on the second support substrate 600, more specifically, on a surface of the protective layer 120 and on a surface of the second barrier layer 230. After the sealing member 150 and the filler 300 are formed, the first support substrate 500 and the components provided thereon, and the second support substrate 600 and the components provided thereon, are bonded together. The bonding may be performed in a reduced pressure atmosphere. Both of, or one of, the sealing member 150 and the filler 300 may be formed of a delayed-curable resin, which is cured gradually after being irradiated with ultraviolet. The sealing member 150 and/or the filler 300 that is formed of such a delayed-curable resin is cured even when, for example, the first or the second barrier layer 210 or 230 has a low ultraviolet transmittance.

FIG. 10 shows a step in the method for producing the display device 20 in embodiment 2 according to the present invention. In the step shown in FIG. 10, the first support substrate 500 and the second support substrate 600 are peeled off. As shown in FIG. 10, the first support substrate 500 and the second support substrate 600 are respectively peeled off from the first substrate 100 and the second substrate 200. As a result, the display device 20 including the flexible first substrate 100, the flexible second substrate 200 and the components sandwiched between the flexible first substrate 100 and the flexible second substrate 200 is formed. The first support substrate 500 and the second support substrate 600 may be peeled off as follows. For example, rear surfaces of the support substrates 500 and 600 (surfaces opposite to surfaces on which the light emitting elements 111 through 113 and the color filters 181 through 183 are formed) are irradiated with laser light to locally heat an interface between the first support substrate 500 and the flexible first substrate 100 and an interface between the second support substrate 600 and the flexible second substrate 200. Alternatively, the first support substrate 500 and the second support substrate 600 may be peeled off as follows. The flexible substrates 100 and 200 are respectively formed on the support substrate 500 and 600 with a UV-curable adhesive layer. After the components including the light emitting elements 111 through 113 and the color filters 181 through 183 are formed on the flexible substrates 100 and 200, the rear surfaces of the support substrates 500 and 600 are irradiated with ultraviolet to denature the UV-curable adhesive layer.

In this manner, the flexible display device 20 in embodiment 2 according to the present invention is produced.

### EMBODIMENT 3

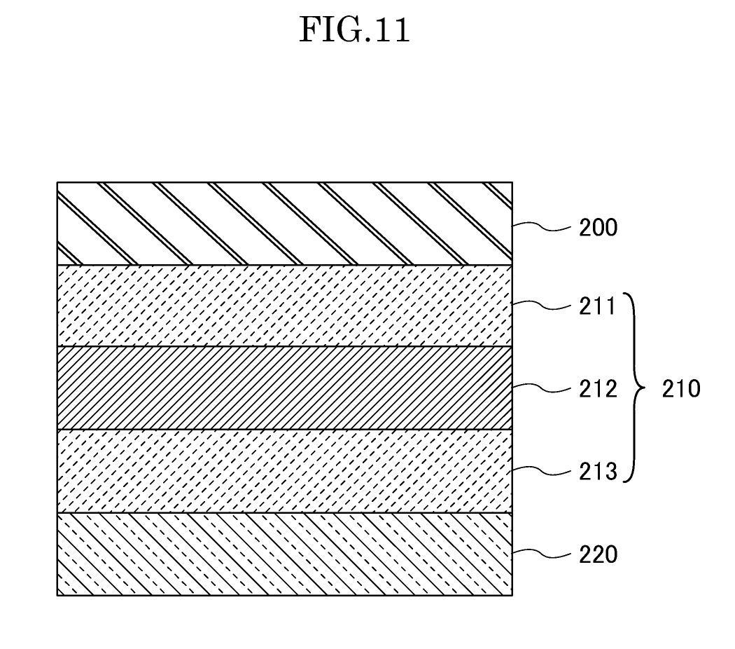

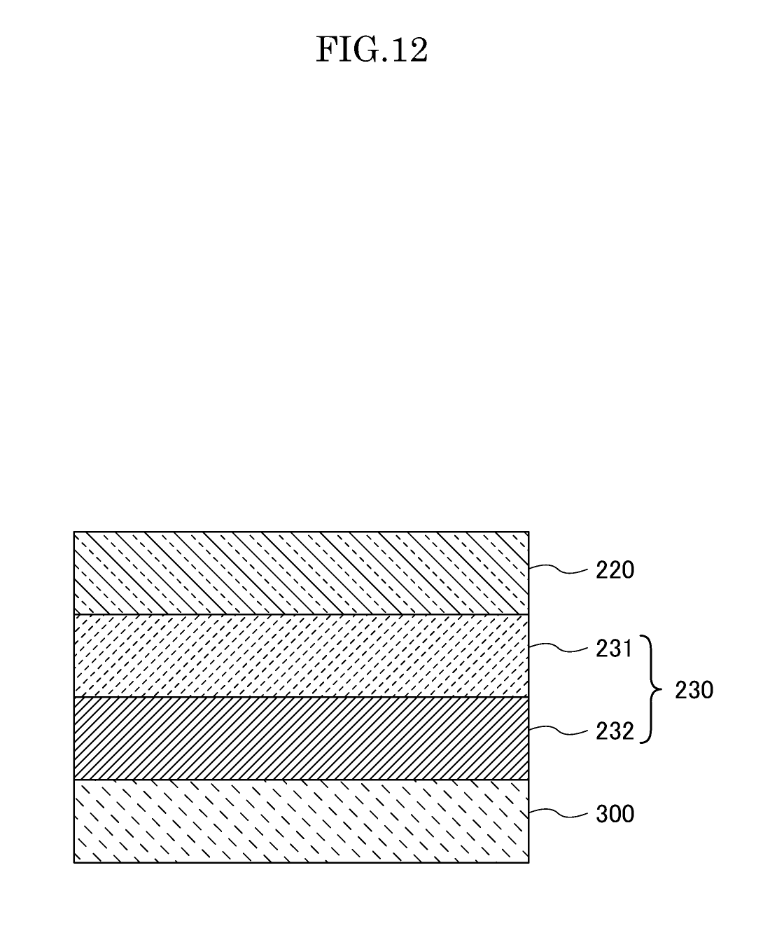

With reference to FIG. 11 and FIG. 12, a layer structure of a display device in embodiment 3 according to the present invention will be described. In embodiment 3, a layer structure of a top emission-type flexible display device will be described as in embodiment 1.

FIG. 11 is a cross-sectional view showing a layer structure of the first barrier layer 210 of the display device in embodiment 3 according to the present invention. Referring to FIG. 11, a structure in which the first barrier layer 210 shown in FIG. 1 includes stacked layers will be described. As shown in FIG. 11, the first barrier layer 210 includes a first damp-proof film 212, a first adhesive film 211 provided between the first damp-proof film 212 and the second substrate 200, and a second adhesive film 213 provided between the first damp-proof film 212 and the organic layer 220. The first adhesive film 211 has a higher level of adhesiveness to the second substrate 200 than the adhesiveness of the first damp-proof film 212 to the second substrate 200. The second adhesive film 213 has a higher level of adhesiveness to the organic layer 220 than the adhesiveness of the first damp-proof film 212 to the organic layer 220.

The first adhesive film 211 and the second adhesive film 213 may each be an SiOₓ film, an SiOₓN_{y} film, or a such a film containing impurities. Alternatively, the first adhesive film 211 and the second adhesive film 213 may each be an AlOₓ film, an AlOₓN_{y} film, any other metal oxide film, or any other metal oxide nitride film. The first damp-proof film 212 has a higher level of dampproofness than that of the first adhesive film 211 and the second adhesive film 213. In the example shown in FIG. 11, the first damp-proof film 212 is sandwiched between the first adhesive film 211 and the second adhesive film 213. The present invention is not limited to such a structure. For example, the first barrier layer 210 may include only one of the first adhesive film 211 and the second adhesive film 213.

As described above, in embodiment 3 according to the present invention, the first adhesive film 211 and the second adhesive film 213 are provided. Even if the adhesiveness between the first damp-proof film 212 and the second substrate 200 or between the first damp-proof film 212 and the organic layer 220 is poor, the structure in embodiment 3 provides both of a high level of adhesiveness and a high level of dampproofness. In the case where, for example, the first damp-proof film 212 is an SiNₓ film or an SiNₓO_{y} film, the first adhesive film 211 provided on the second substrate 200 suppresses the second substrate 200 from being etched by ammonia gas that is used to form the SiNₓ film or an SiNₓO_{y} film.

FIG. 12 is a cross-sectional view showing a layer structure of the second barrier layer 230 of the display device in embodiment 3 according to the present invention. Referring to FIG. 12, a structure in which the second barrier layer 230 shown in FIG. 1 includes stacked layers will be described. As shown in FIG. 12, the second barrier layer 230 includes a second damp-proof film 232 and a third adhesive film 231 provided between the second damp-proof film 232 and the organic layer 220. The third adhesive film 231 has a higher level of adhesiveness to the organic layer 220 than the adhesiveness of the second damp-proof film 232 to the organic layer 220.

The third adhesive film 231 may be an SiOₓ film, an SiOₓN_{y} film, or a such a film containing impurities. Alternatively, the third adhesive film 231 may be an AlOₓ film, an AlOₓN_{y} film, any other metal oxide film, or any other metal oxide nitride film.

The second damp-proof film 232 has a higher level of dampproofness than that of the third adhesive film 231.

As described above, in embodiment 3 according to the present invention, the third adhesive film 231 is provided. Even if the adhesiveness between the second damp-proof film 232 and the organic layer 220 is poor, the structure in embodiment 3 provides both of a high level of adhesiveness and a high level of dampproofness. In the case where, for example, the second damp-proof film 232 is an SiNₓ film or an SiNₓO_{y} film, the third adhesive film 231 provided on the organic layer 220 suppresses the organic layer 220 from being etched by ammonia gas that is used to form the SiNₓ film or an SiNₓO_{y} film.

As described above, the display device in embodiment 3 according to the present invention includes the first through third adhesive films 211, 213 and 231 respectively between the first damp-proof film 212 and the second substrate 200, between the first damp-proof film 212 and the organic layer 220, and between the second damp-proof film 232 and the organic layer 220. Therefore, a high level of adhesiveness is provided.

The present invention is not limited to the above-described embodiments, and may be modified appropriately without departing from the gist of the invention.

What is claimed is:

1. A display device, comprising:
a first substrate;
a light emitting element located on the first substrate;
a second substrate having dampproofness and facing the first substrate;
a first barrier layer located on the second substrate and having a higher level of dampproofness than the dampproofness of the second substrate;
an organic layer located on the first barrier layer at a position facing the light emitting element; and
a second barrier layer located on the organic layer and having a higher level of dampproofness than the dampproofness of the second substrate.

2. The display device according to claim 1, wherein the organic layer includes a color filter part transmitting light of a specific wavelength band.

3. The display device according to claim 1, wherein:
the first barrier layer includes a first damp-proof film containing silicon and nitrogen; and
the second layer includes a second damp-proof film containing silicon and nitrogen.

4. The display device according to claim 3, wherein the first barrier layer includes:
a first adhesive layer provided between the first damp-proof film and the second substrate and having a higher level of adhesiveness to the second substrate than the adhesiveness of the first damp-proof film to the second substrate; and
a second adhesive layer provided between the first damp-proof film and the organic layer and having a higher level of adhesiveness to the organic layer than the adhesiveness of the first damp-proof film to the organic layer.

5. The display device according to claim 4, wherein the first damp-proof film has a higher level of dampproofness than the dampproofness of the first adhesive layer and the second adhesive layer.

6. The display device according to claim 3, wherein the second barrier layer includes a third adhesive film provided between the second damp-proof film and the organic layer and having a higher level of adhesiveness to the organic layer than the adhesiveness of the second damp-proof film to the organic layer.

7. The display device according to claim 6, wherein the second damp-proof film has a higher level of dampproofness than the dampproofness of the third adhesive layer.
